(19) United States
(12) Patent Application Publication
(10) Pub. No.: US 2026/0033375 A1
(43) Pub. Date: Jan. 29, 2026

(54) Method for Producing Molded Electronic Devices

(71) Applicant: Infineon Technologies AG, Neubiberg (DE)

(72) Inventors: Christoph Bayer, Eußenheim (DE); Stefan Wötzel, Erfurt (DE); Marcus Böhm, Mintraching (DE); Thorsten Scharf, Lappersdorf (DE); Julian Treu, München (DE)

(21) Appl. No.: 18/784,225

(22) Filed: Jul. 25, 2024

(51) Int. Cl. H01L 23/00; H01L 21/56

(52) U.S. Cl. CPC H01L 24/97; H01L 21/561; H01L 21/565; H01L 24/83; H01L 24/96; H01L 2224/8382; H01L 2224/96; H01L 2224/97; H01L 2924/13055; H01L 2924/13091

(57) ABSTRACT

A method for producing a molded electronic devices includes providing a first metallic frame including a plurality of die pads and a plurality of first connectors that hold the die pads in place. A vertical power semiconductor die is attached to each die pad. One or more second metallic frames are vertically aligned with the first metallic frame. Each second metallic frame includes a plurality of first contact pads and a plurality of second connectors that hold the first contact pads in place. Each of the first contact pads is attached to a load terminal of one of the vertical power semiconductor dies without any direct physical or electrical connection between the first metallic frame and the second metallic frame. The vertical power semiconductor dies are encapsulated in a mold compound. The first connectors and the second connectors are severed to yield individual molded electronic devices.

### BACKGROUND

Demand for electronic components for power applications continues to increase rapidly across a wide range of industries, including automotive, consumer electronics, renewable energy, manufacturing, and medical, among many others. Developments in semiconductor materials such as silicon carbide (SiC) and gallium nitride (GaN) have enabled power electronic components with advantageous features such as smaller footprint, higher voltage and current capabilities, and faster switching speeds.

Molded electronic devices for power applications offer a number of advantages such as the ability to incorporate complex chip layouts, e.g., system in package (SiP) designs, and provide these as single components that can be built into power modules, systems, and other assemblies. Molded electronic devices include one or more semiconductor dies that are provided on one or more substrates, such as a lead frame, and are embedded in a mold compound. External terminals may be provided on one or more surfaces of the mold compound by metallic bodies, such as copper or aluminum clips and/or die pads, that are attached and electrically coupled to terminals of the semiconductor die(s).

As demand increases, there is a need for solutions that reduce the complexity and cost of manufacturing molded electronic devices.

### SUMMARY

According to an embodiment of a method for producing molded electronic devices, the method comprises: providing a first metallic frame comprising a plurality of die pads and a plurality of first connectors that hold the die pads in place; for each of the die pads, attaching a vertical power semiconductor die to the die pad such that a first load terminal at a first main surface of the vertical power semiconductor die is electrically and physically connected to the die pad and a second load terminal at a second main surface of the vertical power semiconductor die opposite the first main surface faces away from the die pad; vertically aligning one or more second metallic frames with the first metallic frame, each second metallic frame comprising a plurality of first contact pads and a plurality of second connectors that hold the first contact pads in place; for each of the first contact pads, attaching the first contact pad to the second load terminal of one of the vertical power semiconductor dies without any direct physical or electrical connection between the first metallic frame and the second metallic frame; encapsulating the vertical power semiconductor dies in a mold compound such that a surface of the die pads and a surface of the first contact pads that face away from one another are uncovered by the mold compound; and severing the first connectors and the second connectors to yield individual molded electronic devices.

According to another embodiment of a method for producing molded electronic devices, the method comprises: providing a first metallic frame comprising a plurality of die pads and a plurality of first connectors that hold the die pads in place; for each of the die pads, attaching a vertical power semiconductor die to the die pad such that a drain or collector terminal at a first main surface of the vertical power semiconductor die is electrically and physically connected to the die pad and a source or emitter terminal and a gate terminal at a second main surface of the vertical power semiconductor die opposite the first main surface face away from the die pad; vertically aligning one or more second metallic frames with the first metallic frame, each second metallic frame comprising a plurality of first contact pads and a plurality of second connectors that hold the first contact pads in place; for each of the first contact pads, attaching the first contact pad to the source or emitter terminal of one of the vertical power semiconductor dies without any direct physical or electrical connection between the first metallic frame and the second metallic frame; encapsulating the vertical power semiconductor dies in a mold compound such that a surface of the die pads and a surface of the first contact pads that face away from one another are uncovered by the mold compound; and severing the first connectors and the second connectors to yield individual molded electronic devices.

According to another embodiment of a method for producing molded electronic devices, the method comprises: providing a first metallic frame comprising a plurality of die pads and a plurality of first connectors that hold the die pads in place; for each of the die pads, attaching two or more vertical power semiconductor dies to the die pad such that a drain or collector terminal at a first main surface of each of the vertical power semiconductor dies is electrically and physically connected to the die pad and a source or emitter terminal and gate terminal at a second main surface of each of the vertical power semiconductor dies opposite the first main surface face away from the die pad; vertically aligning one or more second metallic frames with the first metallic frame, each second metallic frame comprising a plurality of first contact pads and a plurality of second connectors that hold the first contact pads in place; for each of the first contact pads, attaching the first contact pad to the source or emitter terminal or gate terminal of one of the vertical power semiconductor dies without any direct physical or electrical connection between the first metallic frame and the second metallic frame; encapsulating the vertical power semiconductor dies in a mold compound such that a surface of the die pads and a surface of the first contact pads that face away from one another are uncovered by the mold compound; and severing the first connectors and the second connectors to yield individual molded electronic devices.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a first metallic frame used in a method for producing molded electronic devices, according to an embodiment.

FIGS. 2A-2C illustrate attaching vertical power semiconductor dies to the first metallic frame in a method for producing molded electronic devices, according to an embodiment.

FIGS. 3A-3E illustrate a second metallic frame and third metallic frame used in a method for producing molded electronic devices, according to an embodiment.

FIGS. 4A-4B illustrates vertically aligning the second and third metallic frames and the first metallic frame and attaching the first contact pads and the second contact pads of the second metallic frames to the vertical power semiconductor dies attached to the first metallic frame in a method for producing molded electronic devices, according to an embodiment.

FIGS. 5A-5C illustrate encapsulating the vertical power semiconductor dies in a mold compound in a method for producing molded electronic devices, according to an embodiment.

FIGS. 5A-5B illustrate applying the mold compound so as to encapsulate the vertical power semiconductor dies in the mold compound, according to an embodiment. FIG. 5C illustrates removing a portion of the mold compound, according to an embodiment.

FIG. 6 illustrates simultaneously testing multiple vertical power semiconductor dies in a method for producing molded electronic devices, according to an embodiment.

FIGS. 7A-7B illustrate severing the connectors of the first metallic frame and the second metallic frames to yield individual molded electronic devices in a method for producing molded electronic devices, according to an embodiment. FIG. 7A illustrates severing the connectors of the first metallic frame, according to an embodiment. FIG. 7B illustrates severing the first and second connectors of the second metallic frames to yield individual molded electronic devices, according to an embodiment.

FIG. 8A illustrates a molded electronic device produced by a method for producing molded electronic devices, according to an embodiment.

FIG. 8B illustrates a molded electronic device produced by a method for producing molded electronic devices, according to an embodiment.

FIG. 9 illustrates a perspective view of a power electronics assembly that includes molded electronic devices produced by a method for producing molded electronic devices, according to an embodiment.

### DETAILED DESCRIPTION

Described herein is a method for producing molded electronic devices. The method described herein includes pre-packing vertical power semiconductor dies by attaching a plurality of vertical power semiconductor dies to die pads of a first metallic frame, then attaching contact pads of one or more second metallic frames to a side of the vertical power semiconductor dies opposite the first metallic frame. The die pads of the first metallic frame and the contact pads of each second metallic frame are held together by narrow connectors of the respective metallic frames. A mold compound is then applied to encapsulate portions of the first and second metallic frames and the vertical power semiconductor dies, such that faces of the die pads and contact pads of the first and second metallic frames, respectively, are exposed from the mold compound and provide terminals for the vertical power semiconductor dies. Finally, the connectors of the first and second metallic frames are severed and portions of the mold compound are cut to yield individual molded electronic devices.

The method for producing molded electronic devices described herein may offer a number of advantages when compared to other methods for producing molded electronic devices. For example, attaching the vertical power semiconductor dies to the first metallic frame earlier in the process may reduce handling and breakage of the vertical power semiconductor dies. Using the first and second metallic frames to provide contacts for the vertical semiconductor dies enables complex and/or different die sizes, die quantities, contact layouts, molded electronic device form factors, etc., to be processed on a single first metallic frame. Attaching many vertical power semiconductor dies to a single first metallic frame may also simplify the encapsulation process and enable the use of a universal mold process and/or tools for different pre-package form factors. Also, utilizing metallic frames that include preformed die pads and contact pads (e.g., through stamping, etching, or other means) that are held in place by narrow connectors may reduce the amount of material that must be cut through when singulating the molded electronic devices from the first and second metallic frames, potentially simplifying the singulation process, increasing saw rate, reducing blade wear, etc.

Described next, with reference to the figures, are exemplary embodiments of a method for producing molded electronic devices.

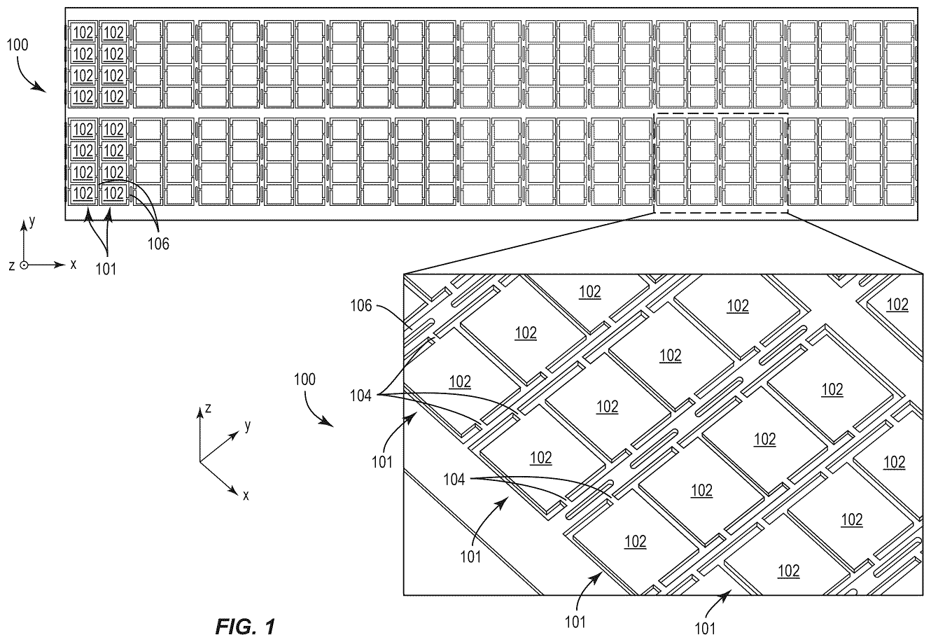

FIG. 1 illustrates a first metallic frame 100 used in a method for producing molded electronic devices, according to an embodiment. The first metallic frame 100 includes a plurality of die pads 102 and a plurality of connectors 104 that hold the die pads 102 in place. The die pads 102 may be provided in, e.g., rows 101 as shown in FIG. 1. The connectors 104 may extended between the die pads 102 and bars 106 that are disposed between each row 101 and are each attached to connectors 104 of adjacent rows 101.

Each row 101 may include the same number of the die pads 102, forming a rectangular or square matrix like the first metallic frame 100 of FIG. 1. In other examples, the rows 101 may be arranged with unequal numbers of die pads 102 across the rows 101.

The first metallic frame 100 may be formed from a sheet, plate, or other body of a metal, metal alloy, or other electrical conductor. For example, the first metallic frame 100 may be formed from a sheet of copper, aluminum, a conductive alloy, etc. The sheet, plate, or other body may be stamped, etched, punched, or otherwise processed to produce the arrangement of the die pads 102, the connectors 104, the bars 106, and any other features of the first metallic frame 100.

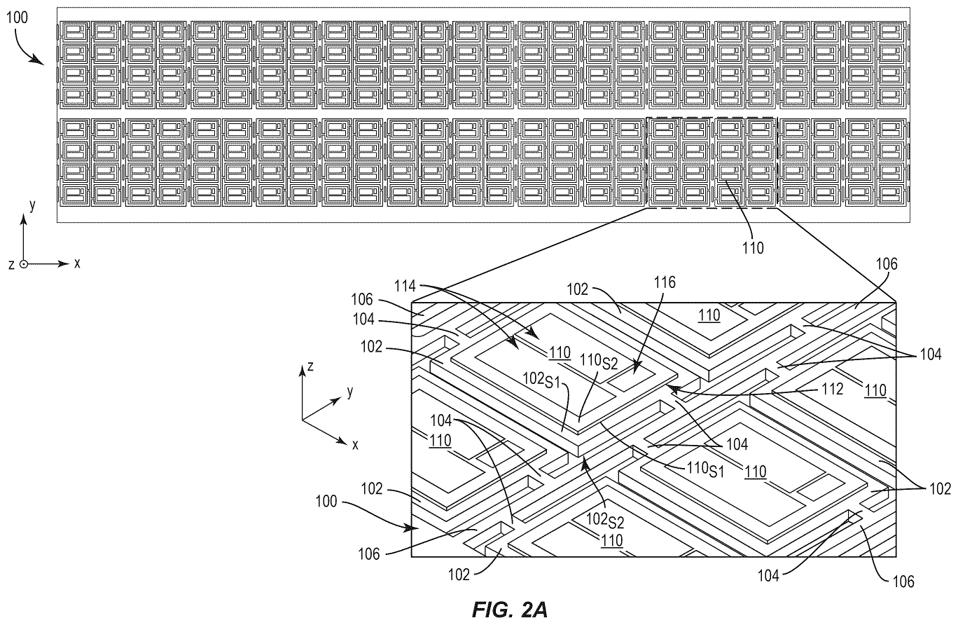

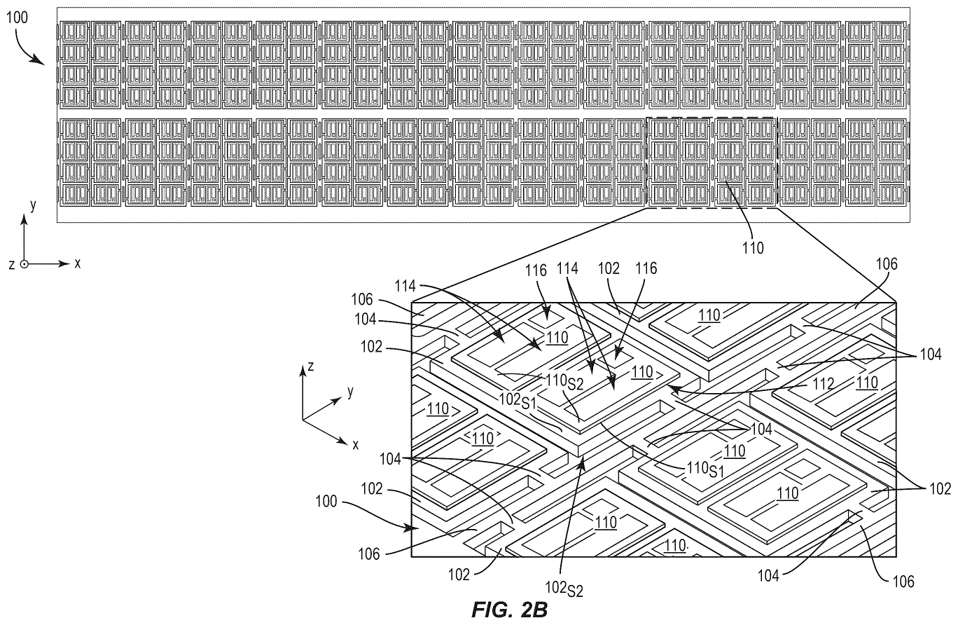

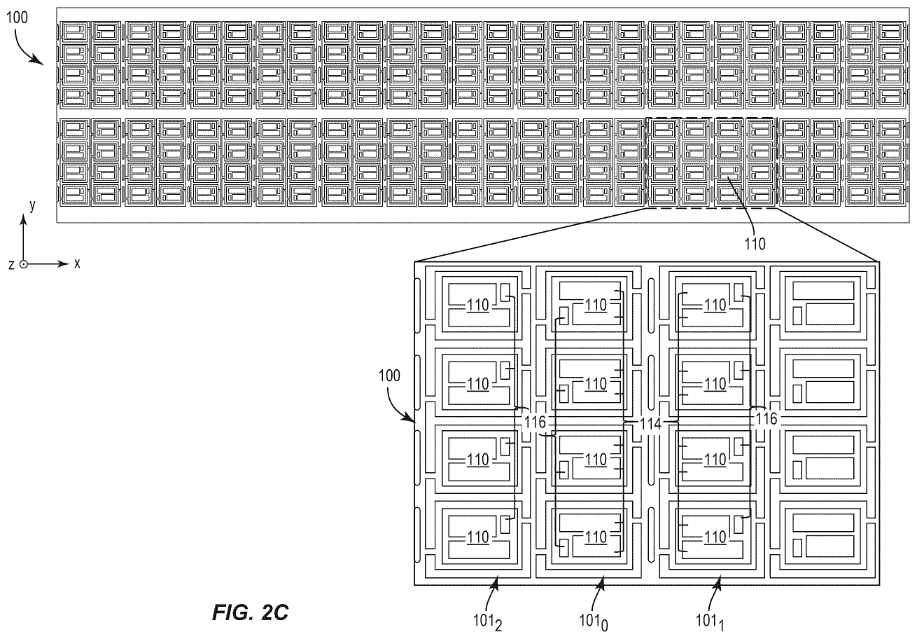

FIG. 2A illustrates attaching vertical power semiconductor dies 110 to the first metallic frame 100 in a method for producing molded electronic devices, according to an embodiment.

In the example of FIG. 2A, a vertical power semiconductor die 110 is attached to each of the die pads 102 of the first metallic frame 100. The vertical power semiconductor dies 110 may be transferred directly from a wafer, e.g., from a thinned and singulated wafer comprising the vertical power semiconductor dies 110 on a tape frame, from sorted vertical power semiconductor dies using, e.g., pick-and-place, or by other means.

In one embodiment, one or more of the vertical power semiconductor dies 110 is a vertical power transistor die. For a vertical power transistor die, the primary current flow path is between the front and back sides of the vertical power semiconductor die 110 (along the z direction in FIG. 2A). In one embodiment, one or more of the vertical power semiconductor dies 110 is a SiC power MOSFET (metal-oxide-semiconductor field-effect transistor) die. One or more of the vertical power semiconductor dies 110 may be a Si power MOSFET die, HEMT (high-electron mobility transistor) die, IGBT (insulated-gate bipolar transistor) die, JFET (junction filed-effect transistor) die, etc. The vertical power semiconductor dies 110 attached to the first metallic frame 100 may all be of a similar or identical design (e.g., device type, structure, materials, dimensions, etc.), or some or each of the vertical power semiconductor dies 110 may have different designs. Various arrangements of designs of vertical power semiconductor dies 110 on the first metallic frame 100 are contemplated.

A vertical power semiconductor die 110 may be attached to a contact pad 102 of the first metallic frame 100 by soldering, diffusion soldering, brazing, adhering, etc. Each vertical power semiconductor die 110 is attached to a die pad 102 of the first metallic frame 100 such that a first load terminal 112 at a first main surface 110_{S1} of a respective vertical power semiconductor die 110 is electrically and physically connected (e.g., by diffusion soldering) to a first main surface 102_{S1} of a respective die pad 102 of the first metallic frame 100. A second main surface 102_{S2} of the respective die pad 102 opposite the first main surface 102_{S1} may form a contact for the first load terminal 112 in a final molded electronic device. A second load terminal 114 and, in some examples, a control terminal 116, at a second main surface 110_{S2} of the respective vertical power semiconductor die 110 opposite the first main surface 110_{S1} face(s) away from the die pad 102 to which the respective vertical power semiconductor die 110 is attached.

In examples where a vertical power semiconductor die 110 is a vertical power transistor die, the first load terminal 112 may be a drain terminal or collector terminal, the second load terminal 114 may be a source terminal or emitter terminal, and the control terminal 116 may be a gate terminal. That is, in such examples, the drain or collector terminal 112 at the first main surface 110_{S1} of a respective vertical power semiconductor die 110 is electrically and physically connected to a respective die pad 102 (e.g., at the first main surface 102_{S1}) of the first metallic frame 100 and the source or emitter terminal 114 and the gate terminal 116 at the second main surface 110_{S2} of the respective vertical power semiconductor die 110 opposite the first main surface 110_{S1} face away from the respective die pad 102.

FIG. 2B illustrates attaching vertical power semiconductor dies 110 to the first metallic frame 100 in a method for producing molded electronic devices, according to an embodiment. In the example of FIG. 2B, two or more vertical power semiconductor dies 110 are attached to each die pad 102. The vertical power semiconductor dies 110, methods of transferring the vertical power semiconductor dies 110 to the first metallic frame 100, methods for attaching the vertical power semiconductor dies 110, etc., described for the embodiment of FIG. 2A may also be used for the embodiment described in FIG. 2B. For example, a drain or collector terminal 112 at a first main surface 110_{S1} of each of two or more respective vertical power semiconductor dies 110 may be electrically and physically connected to the first respective die pad 102. A source or emitter terminal 114 and gate terminal 116 at a second main surface 110_{S2} of each of the two or more respective vertical power semiconductor dies 110 opposite the first main surface 110_{S1} may face away from the respective die pad 102.

FIG. 2C illustrates attaching vertical power semiconductor dies 110 to the first metallic frame 100 in a method for producing molded electronic devices, according to an embodiment. The example of FIG. 2C illustrates one arrangement of the vertical power semiconductor dies 110 on the first metallic frame 100. In this example, the vertical power semiconductor dies 110 are attached to the die pads 102 of the first metallic frame 100 such that the gate terminals 116 of the vertical power semiconductor dies 110 arranged on a particular row 101₀ of the die pads 102 are oriented away from the gate terminals 116 of the vertical power semiconductor dies 110 arranged on a first adjacent row 101₁. The gate terminals 116 of the vertical power semiconductor dies 110 arranged on the particular row 101₀ are oriented toward the gate terminals 116 of the vertical power semiconductor dies 110 arranged on a second oppositely adjacent row 101₂.

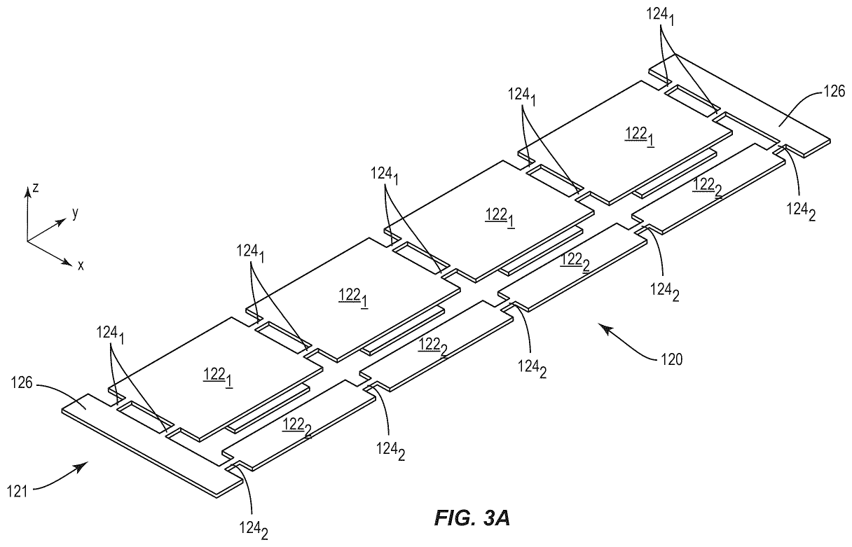

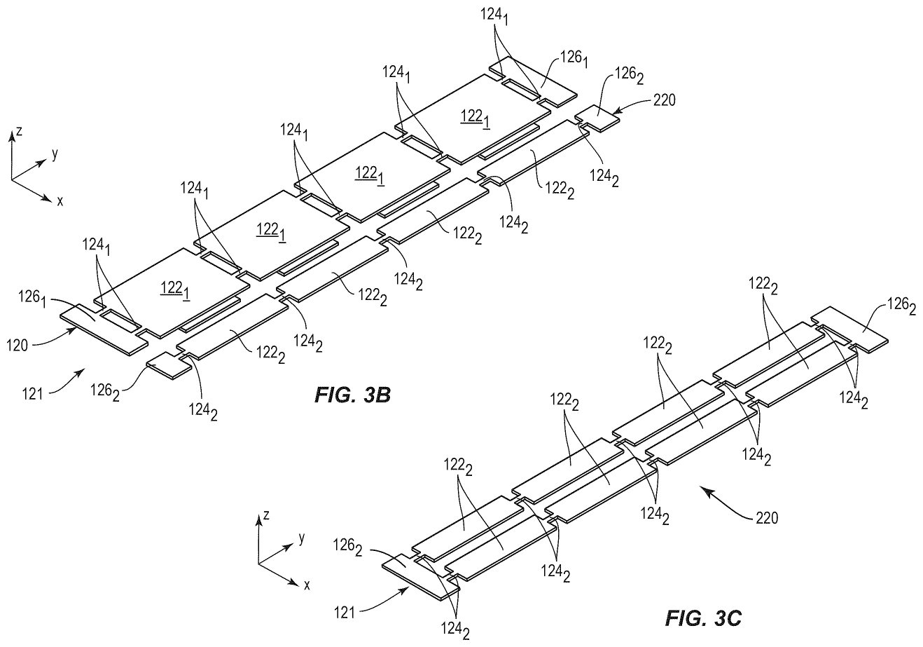

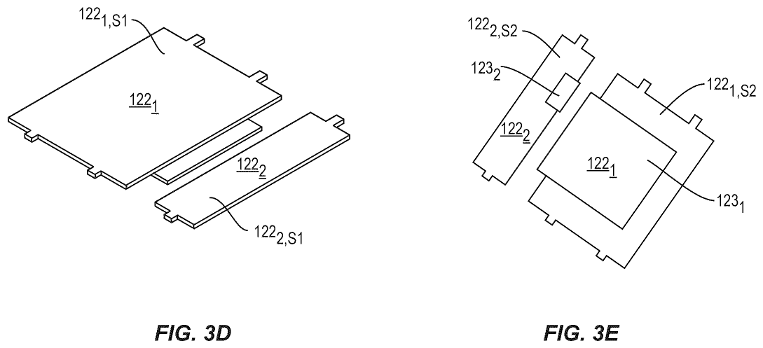

FIGS. 3A-3E illustrate a second metallic frame 120 and third metallic frame 220 used in a method for producing molded electronic devices, according to an embodiment.

In FIG. 3A, the second metallic frame 120 includes a plurality of first contact pads 122₁ and a plurality of first connectors 124₁ that hold the first contact pads 122₁ in place. The first contact pads 122₁ of this example are arranged in a row 121. The second metallic frame 120 may further include a plurality of second contact pads 122₂ and a plurality of second connectors 124₂ that hold the second contact pads 1222 in place. Each second contact pad 122₂ of this example is adjacent to a first contact pad 122₁. The first contact pads 122₁ and the second contact pads 122₂ at each end of the row 121 are attached to an end bar 126 by first and second connectors 124₁ and 124₂, respectively. The row 121 of this example includes four each of the first contact pads 122₁ and the second contact pads 122₂, although the row 121 may include any number first contact pads 122₁ and second contact pads 122₂. Examples in which the second metallic frame 120 includes multiple rows of first contact pads 122₁ and/or second contact pads 122₂ are contemplated.

In FIG. 3B, the second metallic frame 120 includes a plurality of first contact pads 122₁ and a plurality of connectors 124₁ that hold the first contact pads 122₁ in place. The third metallic frame 220 includes a plurality of second contact pads 122₂ and a plurality of second connectors 124₂ that hold the second contact pads 122₂ in place. The first contact pads 122₁ and the second contact pads 122₂ at each end of the row 121 are attached to an end bar 126₁ and 126₂, respectively, by first and second connectors 124₁ and 124₂, respectively. Examples in which either the second metallic frame 120 or the third metallic frame 220 includes multiple rows of first contact pads 122₁ and second contact pads 122₂, respectively, are contemplated.

FIG. 3C illustrates another example of the third metallic frame 220 of FIG. 3B. According to this embodiment, the third metallic frame 220 includes two adjacent rows of second contact pads 122₂. A plurality of second connectors 124₂ hold the second contact pads 122₂ of each adjacent row in place, with the second contact pads 122₂ at each end of the row 121 attached to an end bar 126₂ by the connectors 124₂. Examples in which the third metallic frame 220 includes more than two rows of second contact pads 122₂ are contemplated.

FIG. 3D illustrates a first side of a first contact pad 122₁ and a second contact pad 122₂ (e.g., of the second metallic frame 120 or third metallic frame 220). The first side of the first contact pad 122₁ includes a first surface 122_{1, S1}. The first side of the second contact pad 122₂ includes a first surface 122_{2, S1}.

FIG. 3E illustrates a second side of the first contact pad 122₁ and the second contact pad 122₂ of FIG. 3D that is opposite the first side illustrated in FIG. 3D. The second side of the first contact pad 122₁ includes a second surface 122_{1, S2}. The second side of the second contact pad 122₂ includes a second surface 122_{2, S2}. Each of second surface 122_{1, S2} and 122_{2, S2} may include on or more protruding faces 123₁ and 123₂, respectively. The protruding faces 123₁ and 123₂ may, e.g., be configured to contact a terminal of a vertical power semiconductor die 110.

The second metallic frame 120 and the third metallic frame 220 illustrated in any of FIGS. 3A through 3E may be formed from a sheet, plate, or other body of a metal, metal alloy, or other electrical conductor. For example, the second metallic frame 120 and/or the third metallic frame 220 may be formed from a sheet of copper, aluminum, a conductive alloy, etc. The sheet, plate, or other body may be stamped, etched, punched, or otherwise processed to produce the arrangement of the first contact pads 122₁, the second contact pads 122₂, the first and second connectors 124₁ and 124₂, the end bars 126, 126₁, and 126₂, and any other features of the second metallic frame 120 or the third metallic frame 220.

Some examples described herein refer specifically to a second metallic frame 120 and a separate third metallic frame 220 as illustrated in FIGS. 3B and 3C. However, unless otherwise noted, any of the examples described herein may include any of the examples of the second metallic frame 120 and the third metallic frame 220 as illustrated in FIGS. 3A through 3E.

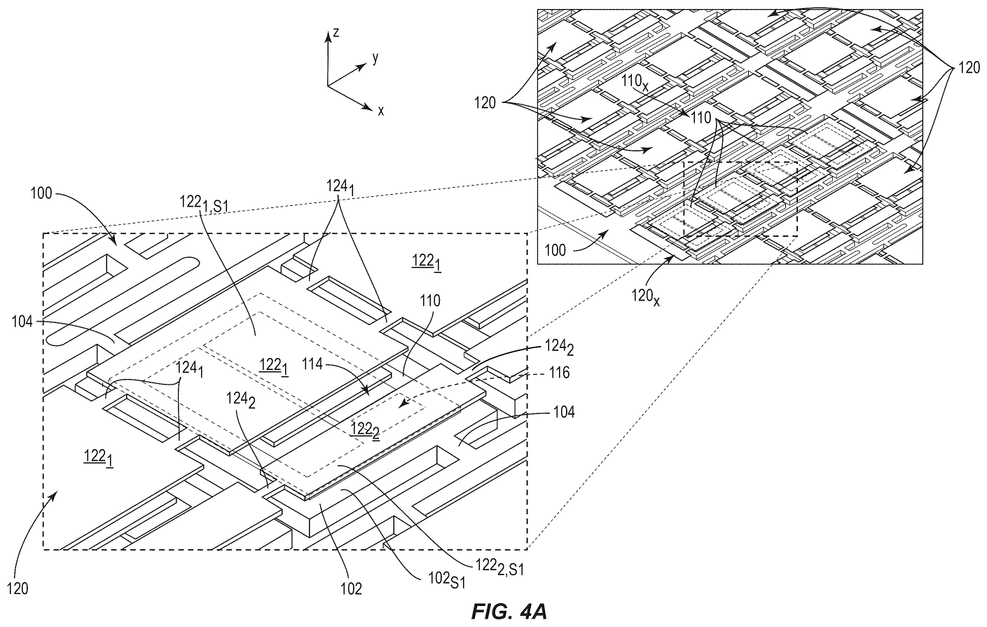

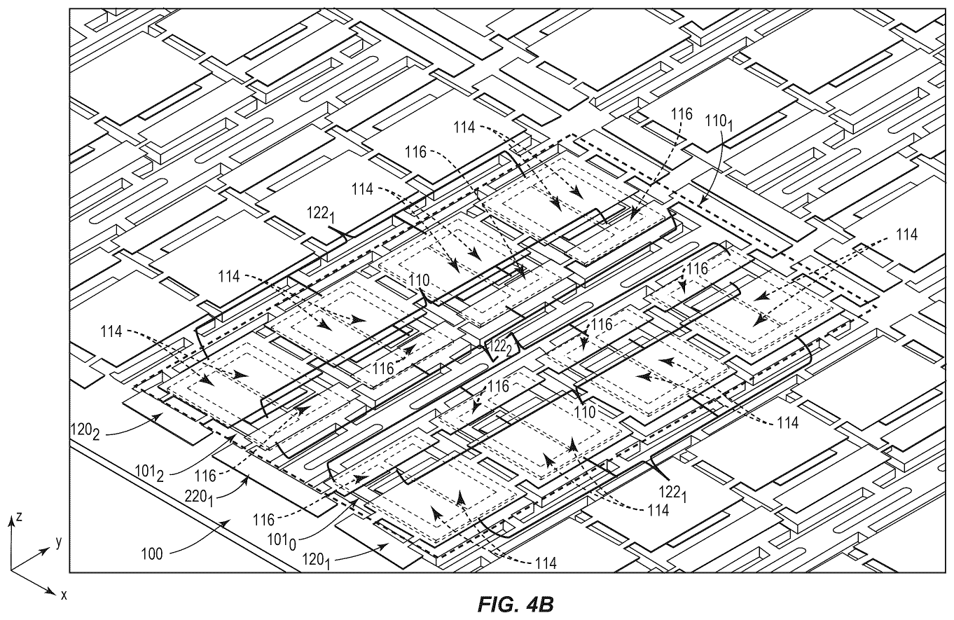

FIG. 4A illustrates vertically aligning each second metallic frame 120 and the first metallic frame 100 and attaching first and second contact pads 122₁ and 122₂ of the second metallic frame(s) 120 to the vertical power semiconductor dies 110 attached to the first metallic frame 100 in a method for producing molded electronic devices, according to an embodiment.

One or more second metallic frames 120 are vertically aligned with the first metallic frame 100, e.g., in the z direction. Each second metallic frame 120 of FIG. 4A is vertically aligned with the first metallic frame 100 such that the connectors 104 of the first metallic frame 100 extend in a first lateral direction x and the first and second connectors 124₁ and 124₂ of each second metallic frame 120 extend in a second lateral direction y that is orthogonal to the first lateral direction x.

Each of the first contact pads 122₁ of the one or more second metallic frames 120 is attached to the second load terminal 114 (e.g., the source or emitter terminal 114) of one of the vertical power semiconductor dies 110. In examples in which one or more of the second metallic frames 120 includes second contact pads 122₂, each of the second contact pads 122₂ of the one or more second metallic frames 120 may be attached to the control terminal 116 (e.g., a gate terminal 116) of one of the vertical power semiconductor dies 110. In some examples, a first contact pad 122₁ and an adjacent second contact pad 122₂ of a second metallic frame 120 of FIG. 3A are attached to a source or emitter terminal 114 and a gate terminal 116, respectively, of a respective vertical power semiconductor die 110. In some examples, a first contact pad 122₁, is attached to the second load terminal 114 of a vertical power semiconductor die 110 at a protruding face of the first contact pad 122₁, e.g., the protruding face 123₁ of the second surface 122_{1, S2} of FIG. 3E. Likewise, a second contact pad 122₂ may be attached to the control terminal 116 of a vertical power semiconductor die 110 at a protruding face of a second contact pad 122₂, e.g., the protruding face 123₂ of the second surface 122_{2, S2} of FIG. 3E. Attaching a first contact pad 122₁ and a second contact pad 122₂ of a second metallic frame 120 to a second load terminal 114 and a control terminal 116, respectively, of a vertical power semiconductor die 110 may include sintering (e.g., Ag or Cu sintering, hybrid sintering), soldering (e.g., diffusion soldering, soft soldering), or other attachment means.

The first contact pads 122₁ and the second contact pads 122₂ of a respective second metallic frame 120 are attached to the vertical power semiconductor dies 110 without any direct physical or electrical connection between the first metallic frame 100 and the respective second metallic frame 120. That is, there is no direct physical or electrical connection between the first metallic frame 100 and any second metallic frame 120. Each of the first contact pads 122₁ and the second contact pads 122₂ of a respective second metallic frame 120 is attached to a respective vertical power semiconductor die 110 such that the surfaces 122_{1, S1} and 122_{2, S1} of the first contact pad 122₁ and the second contact pad 122₂, respectively, face away from the first main surface 102_{S1} of the die pad 102 to which the respective vertical power semiconductor die 110 is attached. A subset 110ₓ of the vertical power semiconductor dies 110 comprises all of the vertical power semiconductor dies 110 having a second load terminal 114 and a control terminal 116 attached to a first contact pad 122₁ and a second contact pad 122₂, respectively, of a particular second metallic frame 120ₓ.

FIG. 4B illustrates vertically aligning each second metallic frame 120 (120₁ and 120₂) and third metallic frame 220 (220₁) and the first metallic frame 100 and attaching the first contact pads 122₁ of the second metallic frame(s) 120 and the second contact pads 122₂ of the third metallic frame(s) 220 to vertical power semiconductor dies 110 attached to the first metallic frame 100 in a method for producing molded electronic devices, according to an embodiment.

In this example, second metallic frames 120₁ and 120₂ and a third metallic frame 220₁ are identified for illustration and discussion. The second metallic frames 120₁ and 120₂ shown in FIG. 4B are examples of the second metallic frame 120 of FIG. 3B. The third metallic frame 220₁ is an example of the third metallic frame 220 of FIG. 3C in that it includes two adjacent rows of second contact pads 122₂. The second metallic frames 120₁ and 120₂ and the third metallic frame 220₁ in FIG. 4B are vertically aligned with the first metallic frame 100, e.g., in the z direction. Each of the second metallic frames 120₁ and 120₂ and the third metallic frame 220₁ of FIG. 4B is vertically aligned with the first metallic frame 100 such that the connectors 104 of the first metallic frame 100 extend in the first lateral direction x and the first connectors 124₁ of the second metallic frames 120₁ and 120₂ and the second connectors 124₂ of the third metallic frame 220₁ extend in the second lateral direction y.

A subset 110₁ of the vertical power semiconductor dies 110 of FIG. 4B comprises a quantity (in this example, four) of the vertical power semiconductor dies 110 on a first row 101₀ and an equal quantity of the vertical power semiconductor dies 110 on an adjacent second row 101₂. The source or emitter terminals 114 of the vertical power semiconductor dies 110 on the first row 101₀ of the subset 110₁ are attached to first contact pads 122₁ of the second metallic frame 120₁. The source or emitter terminals 114 of the vertical power semiconductor dies 110 of the subset 110₁ on the adjacent second row 101₂ are attached to first contact pads 122₁ of the second metallic frame 120₂. The gate terminals 116 of all of the vertical power semiconductor dies 110 of the subset 110₁ are attached to second contact pads 122₂ of the third metallic frame 220₁.

In FIG. 4B, the first contact pads 122₁ of the second metallic frames 120₁ and 120₂ and the second contact pads 122₂ of the third metallic frame 220₁ are attached to the source or emitter terminals 114 and the gate terminals 116, respectively, of the vertical power semiconductor dies 110 of the subset 110₁ without any direct physical or electrical connection between the first metallic frame 100 and the second metallic frames 120₁ and 120₂ and the third metallic frame 220₁.

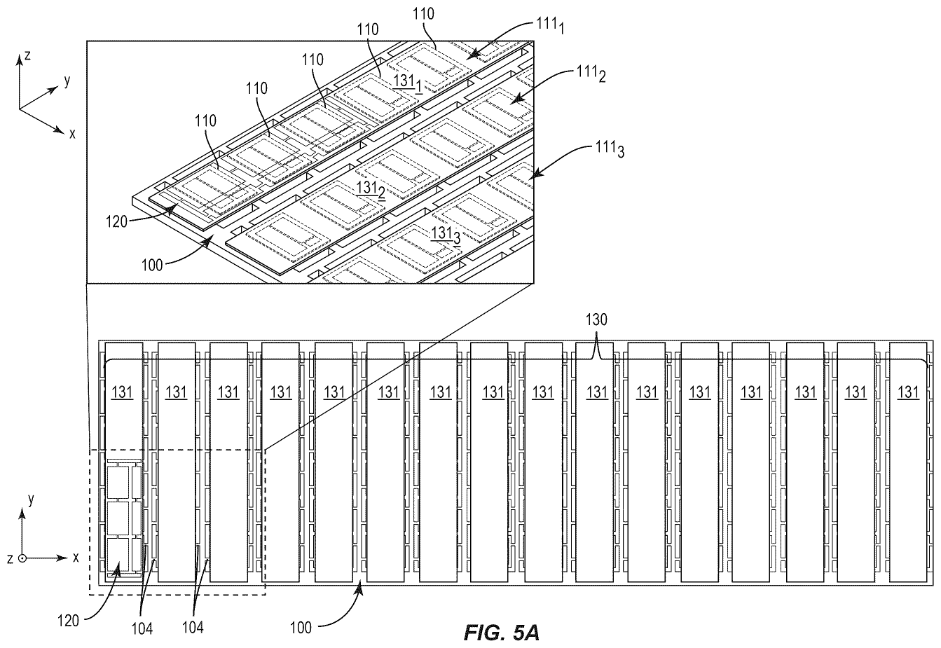

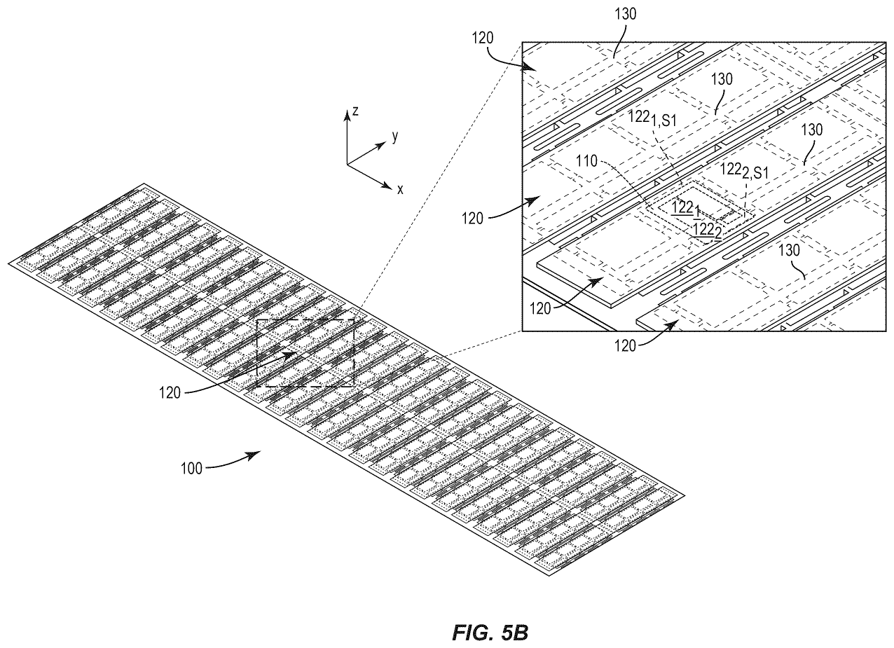

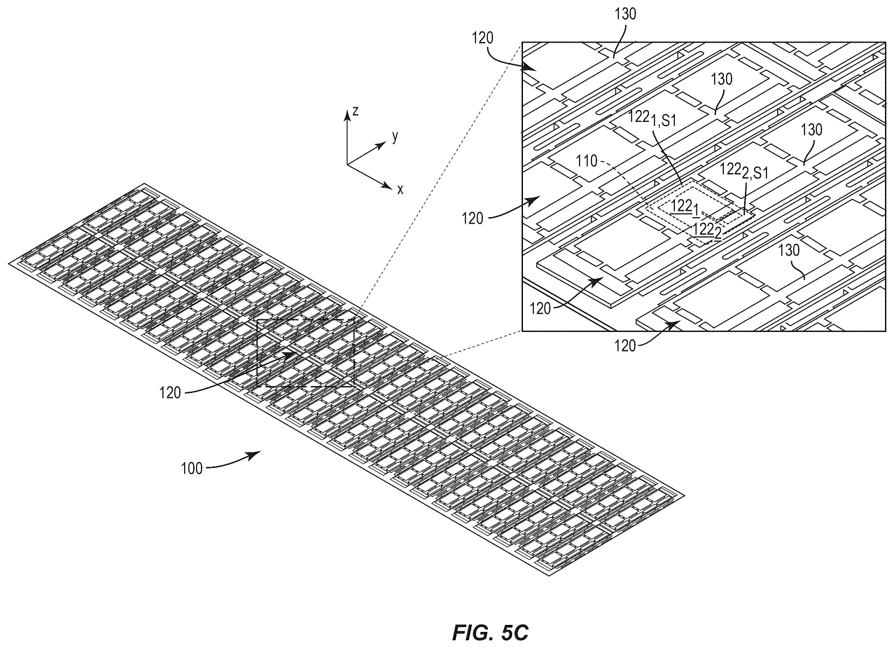

FIGS. 5A-5C illustrate encapsulating the vertical power semiconductor dies 110 in a mold compound 130 in a method for producing molded electronic devices, according to an embodiment. A mold compound is a plastic encapsulant typically formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. The mold compound may be formed by injection molding, compression molding, film-assisted molding (FAM), reaction injection molding (RIM), resin transfer molding (RTM), blow molding, etc.

FIG. 5A illustrates applying the mold compound 130 so as to encapsulate the vertical power semiconductor dies 110 in the mold compound 130. Encapsulating the vertical power semiconductor dies 110 in the mold compound 130 may include applying the mold compound 130 in discrete segments 131, wherein each discrete segment 131 of the mold compound 130 encapsulates a subset of the vertical power semiconductors dies 110 arranged in one or more rows 111ₓ. For example, FIG. 5A illustrates rows 111₁, 111₂, and 111₃ of vertical power semiconductor dies 110 each encapsulated by a discrete segment 131₁, 131₂, and 131₃ of the mold compound 130, respectively. Adjacent discrete segments 131 of the mold compound 130 in this example are separated from one another by one or more connectors 104 of the first metallic frame 100. The mold compound 130 may be applied using map molding to produce the discrete segments 131. Applying the mold compound 130 may also be done using film-assisted molding (FAM), transfer molding (TM), among other techniques.

FIG. 5B illustrates applying the mold compound 130 so as to encapsulate the vertical power semiconductor dies 110 in the mold compound 130. In the example of FIG. 5B, encapsulating the vertical power semiconductor dies 110 in the mold compound 130 includes applying the mold compound 130 such that the first surface 122_{1, S1} of each of the first contact pads 122₁ and the first surface 122_{2, S1} of each of the second contact pads 122₂ are covered by the mold compound 130.

FIG. 5C illustrates removing a portion of the mold compound 130. A portion of the mold compound 130 may be removed such that that the first surface 122_{1, S1} of each of the first contact pads 122₁ and the first surface 122_{2, S1} of each of the second contact pads 122₂ are uncovered by the mold compound 130 while the mold compound 130 remains around the first contact pads 122₁, the second contact pads 122₂, and the vertical power semiconductor dies 110. The portion of the mold compound 130 may be removed by grinding, lapping, and/or other techniques.

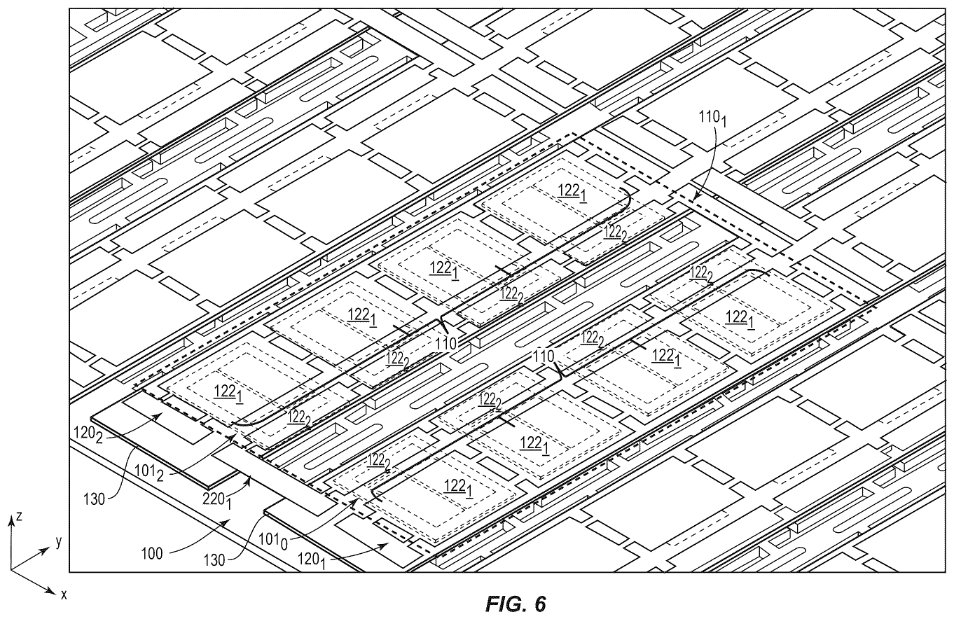

FIG. 6 illustrates simultaneously testing multiple vertical power semiconductor dies 110 in a method for producing molded electronic devices, according to an embodiment.

FIG. 6 illustrates simultaneously testing in parallel each the vertical power semiconductor dies 110 of the subset 110₁ illustrated in the arrangement of FIG. 4B, although the methods described herein may be applied to other arrangements of the first metallic frame 100, the second metallic frames 120 (e.g., 120₁ and/or 120₂), the third metallic frames 220 (e.g., 220₁), and the vertical power semiconductor dies 110.

The vertical power semiconductor dies 110 on one or both of the rows 101₀ and 101₂ may be simultaneously tested by applying biases to one or more of the first metallic frame 100, the second metallic frames 120₁ and 120₂, and the third metallic frame 220₁. Applying a bias to one or both of the second metallic frames 120₁ and 120₂, for example, applies the bias to all of the first contact pads 122₁ and thus to the source or emitter terminal 114 of each power semiconductor die 110 of the respective row 101₀ and 101₂, as the first contact pads 122₁ of each of the second metallic frames 120₁ and 120₂ are connected by first connectors 124₁. Likewise, applying a bias to the third metallic frame 220₁ applies the bias to all of the second contact pads 122₂ of, in this example, both rows 101₀ and 101₂, and thus to the gate terminal 116 of each power semiconductor die 110 of rows 101₀ and 101₂. That is, the testing according to this method may include applying a source or emitter bias to each of the second metallic frames 120₁ and 120₂ and applying a gate bias to the third metallic frame 220₁. The respective biases that are applied to the second metallic frames 120₁ and 120₂ and the third metallic frame 220₁ may be applied relative to the first metallic frame 100 since, as noted previously, the first contact pads 122₁ and the second contact pads 122₂ of a respective second metallic frame 120 (in this example, the second metallic frames 120₁ and 120₂ and the third metallic frame 220₁) are attached to the vertical power semiconductor dies 110 without any direct physical or electrical connection between the first metallic frame 100 and the respective second metallic frame 120.

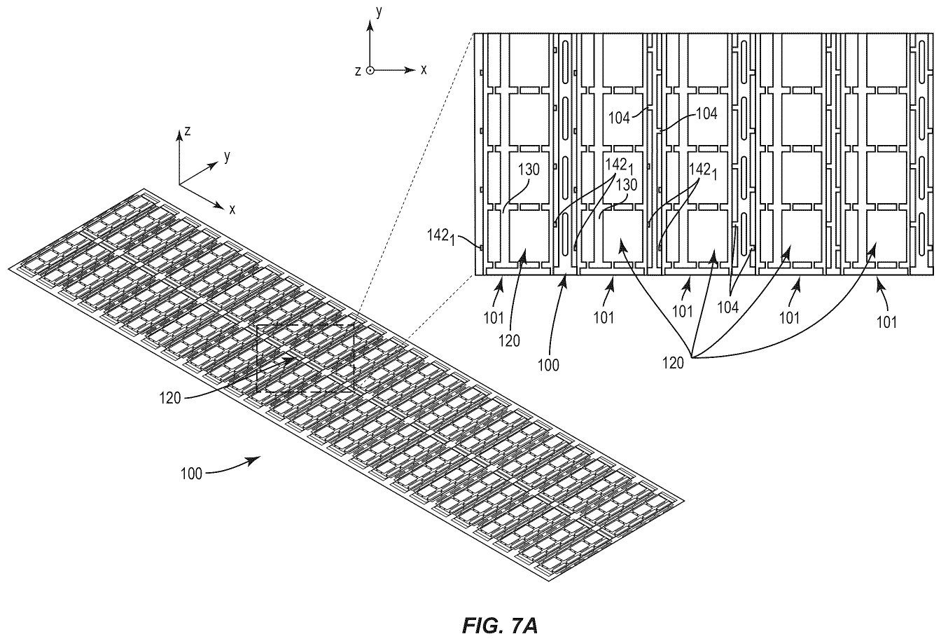

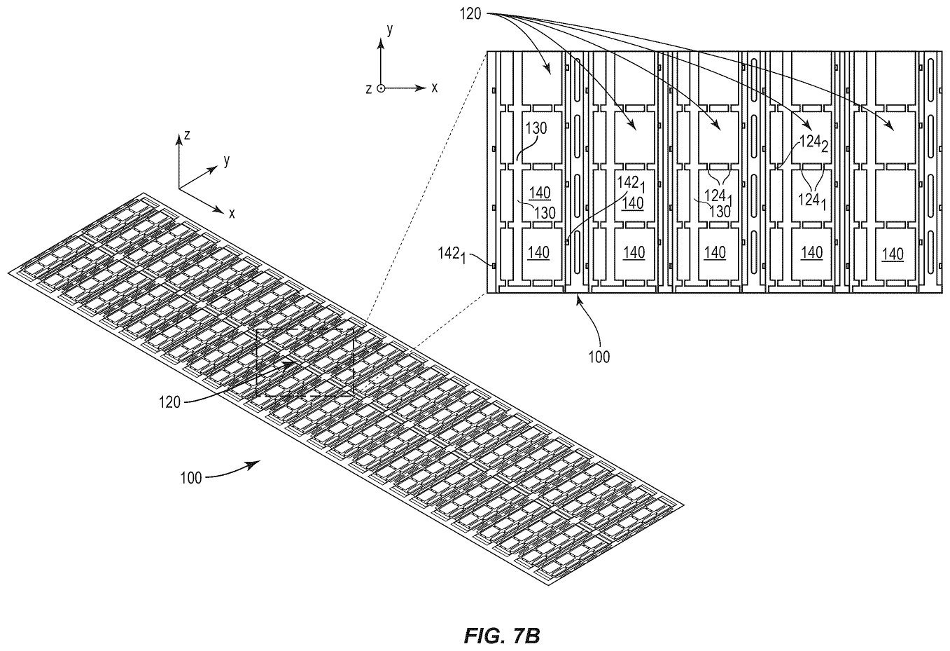

FIGS. 7A-7B illustrate severing the connectors 104, 124₁, and 124₂ of the first metallic frame 100 and the second metallic frames 120 to yield individual molded electronic devices 140 in a method for producing molded electronic devices, according to an embodiment.

FIG. 7A illustrates severing the connectors 104 of the first metallic frame 100, according to an embodiment. The connectors 104 of the first metallic frame 100 may be severed by cutting, e.g., sawing, between the rows 101 along the second lateral direction y. After severing the connectors 104, tabs 142₁ that each comprise a remnant of a severed connector 104 protrude from the mold compound 130 in the first lateral direction x.

FIG. 7B illustrates severing the first and second connectors 124₁ and 124₂ of the second metallic frames 120 to yield individual molded electronic devices 104, according to an embodiment. The first and second connectors 124₁ and 124₂ of the second metallic frames 120 may be severed by cutting, e.g., sawing, through the first and second connectors 124₁ and 124₂ and a portion of the mold compound 130 along the first lateral direction x. The connectors 104 of the first metallic frame 100, the first and second connectors 124₁ and 124₂ of the second metallic frames 120, and the portion of the mold compound 130 may be cut using the same cutting tool. Cutting through the connectors 104 of the first metallic frame 100, the first and second connectors 124₁ and 124₂ of the second metallic frames 120, and the portion of the mold compound 130 yields individual molded electronic devices 140.

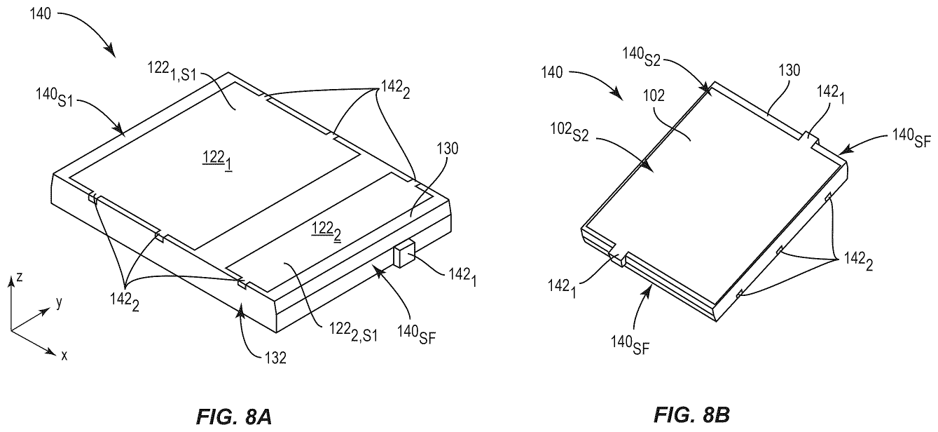

FIG. 8A illustrates a molded electronic device 140 produced by a method for producing molded electronic devices, according to an embodiment.

The first surface 122_{1, S1} of a first contact pad 122₁ and the first surface 122_{2, S1} of a second contact pad 122₂ are exposed from the mold compound 130 on a first main surface 140_{S1} of the molded electronic device 140. The exposed first surfaces 122_{1, S1} and 122_{2, S1} may form terminals of the molded electronic device 140, e.g., a source or emitter terminal and a gate terminal, respectively.

The molded electronic device 140 includes one or more tabs 142₁ that protrude from a side face 140_{SF} of the mold compound 130 of the individual molded electronic device 140 along the second lateral direction y. Each tab 142₁ that protrudes from a side face 140_{SF} comprises a remnant of a severed connector 104 of the first metallic frame 100. Tabs 142₂ comprising remnants of severed first connectors 124₁ and/or second connectors 124₂ are flush with a cut portion 132 of the mold compound 130 of molded electronic device 140 along the first lateral direction x.

FIG. 8B illustrates a molded electronic device 140 produced by a method for producing molded electronic devices, according to an embodiment. FIG. 8B illustrates a second main surface 140_{S2} of the individual molded electronic device 140 of FIG. 8A that is opposite the first main surface 140_{S1}. The second main surface 102_{S2} of a die pad 102 (e.g., the second main surface 102_{S2} of FIG. 2A) is exposed from the mold compound 130 on the second main surface 140_{S2} and faces away from the first surface 122_{1, S1} of the first contact pad 122₁ and the first surface 122_{2, S1} of the second contact pad 122₂. The second main surface 102_{S2} of the die pad 102 may form a terminal of the molded electronic device 140, e.g., a drain or collector terminal.

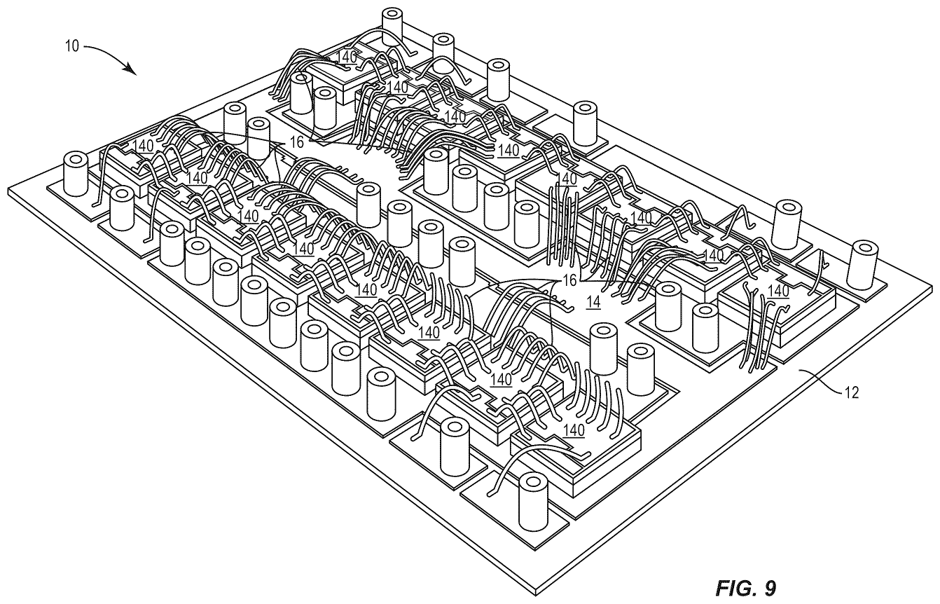

FIG. 9 illustrates a perspective view of a power electronics assembly 10 that includes molded electronic devices 140 produced by a method for producing molded electronic devices, according to an embodiment. The power electronics assembly 10 includes molded electronic devices 140 attached and electrically coupled to a DCB (direct copper bonded) substrate 12. The molded electronic devices 140 may alternatively be attached and electrically coupled to a different substrate such as a lead frame, an insulated metal substrate (IMS), a PCB (printed circuit board), an AMB (active metal brazed), etc. One or more terminals of the molded electronic devices 140, e.g. terminals formed by surfaces 122_{1, S1}, 122_{2, S1}, and/or 102_{S2}, may be attached to traces 14 of the printed circuit board 12. The terminals may be attached directly, e.g., by soldering, or by wire bonds 16.

Although the present disclosure is not so limited, the following numbered examples demonstrate one or more aspects of the disclosure.

Example 1. A method, comprising: providing a first metallic frame comprising a plurality of die pads and a plurality of first connectors that hold the die pads in place; for each of the die pads, attaching a vertical power semiconductor die to the die pad such that a first load terminal at a first main surface of the vertical power semiconductor die is electrically and physically connected to the die pad and a second load terminal at a second main surface of the vertical power semiconductor die opposite the first main surface faces away from the die pad; vertically aligning one or more second metallic frames with the first metallic frame, each second metallic frame comprising a plurality of first contact pads and a plurality of second connectors that hold the first contact pads in place; for each of the first contact pads, attaching the first contact pad to the second load terminal of one of the vertical power semiconductor dies without any direct physical or electrical connection between the first metallic frame and the second metallic frame; encapsulating the vertical power semiconductor dies in a mold compound such that a surface of the die pads and a surface of the first contact pads that face away from one another are uncovered by the mold compound; and severing the first connectors and the second connectors to yield individual molded electronic devices.

Example 2: The method of example 1, wherein each second metallic frame is vertically aligned with the first metallic frame such that the first connectors of the first metallic frame extend in a first lateral direction and the second connectors of each second metallic frame extend in a second lateral direction that is orthogonal to the first lateral direction.

Example 3: The method of example 1 or 2, wherein an individual molded electronic device comprises one or more tabs that protrude from a side face of the mold compound of the individual molded electronic device, each tab comprising a remnant of a severed first connector or a severed second connector.

Example 4: The method of any of examples 1 through 3, wherein severing the first connectors and the second connectors comprises severing the first connectors by cutting along a first lateral direction and severing the second connectors by cutting along a second lateral direction that is orthogonal to the first lateral direction.

Example 5: The method of example 4, wherein after severing the first connectors along the first lateral direction, tabs comprising remnants of severed first connectors protrude from the mold compound of individual molded electronic devices along the first lateral direction, and wherein severing the second connectors comprises cutting the second connectors and a portion of the mold compound using a same cutting tool, such that tabs comprising remnants of severed second connectors are flush with a cut portion of the mold compound of individual molded electronic devices along the second lateral direction.

Example 6: The method of any of examples 1 through 5, wherein attaching a vertical power semiconductor die to a die pad comprises diffusion soldering.

Example 7: The method of any of examples 1 through 6, wherein attaching a first contact pad to a second load terminal of a vertical power semiconductor die comprises at least one of sintering, diffusion soldering, or soldering.

Example 8: The method of any of examples 1 through 7, wherein encapsulating the vertical power semiconductor dies in a mold compound comprises applying the mold compound in discrete segments, wherein each discrete segment of the mold compound encapsulates a subset of the vertical power semiconductors dies.

Example 9: The method of example 8, wherein the vertical power semiconductor dies of a subset are arranged in one or more rows.

Example 10: The method of example 8, wherein adjacent discrete segments of the mold compound are separated from one another by one or more first connectors of the first metallic frame.

Example 11: The method of any of examples 1 through 10, wherein encapsulating the vertical power semiconductor dies in a mold compound comprises: applying the mold compound such that the surface of the first contact pads is covered by the mold compound; and removing a portion of the mold compound to uncover the surface of the first contact pads.

Example 12: The method of any of examples 1 through 11, wherein a plurality of second metallic frames are vertically aligned with the first metallic frame, wherein a subset of the vertical power semiconductor dies comprises all the vertical power semiconductor dies having a second load terminal attached to a first contact pad of a particular second metallic frame, and wherein the method further comprises testing in parallel each vertical power semiconductor die of the subset, the testing comprising applying a bias to the particular second metallic frame.

Example 13: The method of any of examples 1 through 12, wherein each vertical power semiconductor die further comprises a control terminal at the second main surface of the vertical power semiconductor die, wherein each second metallic frame further comprises a plurality of second contact pads and a plurality of third connectors that hold the second contact pads in place, and wherein the method further comprises: for each of the second contact pads, attaching the second contact pad to the control terminal of one of the vertical power semiconductor dies without any direct physical or electrical connection between the first metallic frame and the second metallic frame; encapsulating the vertical power semiconductor dies in the mold compound such that a surface of the second contact pads that faces away from the surface of the die pads is uncovered by the mold compound; and severing the third connectors to yield individual molded electronic devices.

Example 14: The method of example 13, wherein each first load terminal is a drain terminal or collector terminal of a vertical power semiconductor die, wherein each second load terminal is a source terminal or emitter terminal of a vertical power semiconductor die, and wherein each control terminal is a gate terminal of a vertical power semiconductor die.

Example 15: A method, comprising: providing a first metallic frame comprising a plurality of die pads and a plurality of first connectors that hold the die pads in place; for each of the die pads, attaching a vertical power semiconductor die to the die pad such that a drain or collector terminal at a first main surface of the vertical power semiconductor die is electrically and physically connected to the die pad and a source or emitter terminal and a gate terminal at a second main surface of the vertical power semiconductor die opposite the first main surface face away from the die pad; vertically aligning one or more second metallic frames with the first metallic frame, each second metallic frame comprising a plurality of first contact pads and a plurality of second connectors that hold the first contact pads in place; for each of the first contact pads, attaching the first contact pad to the source or emitter terminal of one of the vertical power semiconductor dies without any direct physical or electrical connection between the first metallic frame and the second metallic frame; encapsulating the vertical power semiconductor dies in a mold compound such that a surface of the die pads and a surface of the first contact pads that face away from one another are uncovered by the mold compound; and severing the first connectors and the second connectors to yield individual molded electronic devices.

Example 16: The method of example 15, wherein each second metallic frame further comprises a plurality of second contact pads and a plurality of third connectors that hold the second contact pads in place, and wherein the method further comprises: for each of the second contact pads, attaching the second contact pad to the gate terminal of one of the vertical power semiconductor dies without any direct physical or electrical connection between the first metallic frame and the second metallic frame; encapsulating the vertical power semiconductor dies in the mold compound such that a surface of the second contact pads that faces away from the surface of the die pads is uncovered by the mold compound; and severing the third connectors to yield individual molded electronic devices.

Example 17: The method of example 15 or 16, further comprising: vertically aligning one or more third metallic frames with the first metallic frame, each third metallic frame comprising a plurality of second contact pads and a plurality of third connectors that hold the second contact pads in place; for each of the second contact pads, attaching the second contact pad to the gate terminal of one of the vertical power semiconductor dies without any direct physical or electrical connection between the first metallic frame and the third metallic frame; encapsulating the vertical power semiconductor dies in a mold compound such that a surface of the second contact pads that faces away from the surface of the die pads is uncovered by the mold compound; and severing the third connectors to yield individual molded electronic devices.

Example 18: The method of example 17, wherein the die pads of the first metallic frame are provided in rows, wherein the vertical power semiconductor dies are attached to the die pads such that the gate terminals of the vertical power semiconductor dies arranged on a particular row are oriented away from the gate terminals of the vertical power semiconductor dies arranged on a first adjacent row and the gate terminals of the vertical power semiconductor dies arranged on the particular row are oriented toward the gate terminals of the vertical power semiconductor dies arranged on a second oppositely adjacent row, wherein a subset of the vertical power semiconductor dies comprises a quantity of the vertical power semiconductor dies on a first row and an equal quantity of the vertical power semiconductor dies on an adjacent second row, wherein the source or emitter terminals of the vertical power semiconductor dies of the subset on the first row are attached to first contact pads of one particular second metallic frame, wherein the source or emitter terminals of the vertical power semiconductor dies of the subset on the second row are attached to first contact pads of another particular second metallic frame, and wherein the gate terminals of all the vertical power semiconductor dies of a subset are attached to second contact pads of a particular third metallic frame.

Example 19: The method of example 18, wherein the method further comprises testing in parallel each vertical power semiconductor die of a subset, the testing comprising applying a source or emitter bias to each of the particular second metallic frames and applying a gate bias to the particular third metallic frame.

Example 20: A method, comprising: providing a first metallic frame comprising a plurality of die pads and a plurality of first connectors that hold the die pads in place; for each of the die pads, attaching two or more vertical power semiconductor dies to the die pad such that a drain or collector terminal at a first main surface of each of the vertical power semiconductor dies is electrically and physically connected to the die pad and a source or emitter terminal and gate terminal at a second main surface of each of the vertical power semiconductor dies opposite the first main surface face away from the die pad; vertically aligning one or more second metallic frames with the first metallic frame, each second metallic frame comprising a plurality of first contact pads and a plurality of second connectors that hold the first contact pads in place; for each of the first contact pads, attaching the first contact pad to the source or emitter terminal or gate terminal of one of the vertical power semiconductor dies without any direct physical or electrical connection between the first metallic frame and the second metallic frame; encapsulating the vertical power semiconductor dies in a mold compound such that a surface of the die pads and a surface of the first contact pads that face away from one another are uncovered by the mold compound; and severing the first connectors and the second connectors to yield individual molded electronic devices.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method, comprising:
providing a first metallic frame comprising a plurality of die pads and a plurality of first connectors that hold the die pads in place;
for each of the die pads, attaching a vertical power semiconductor die to the die pad such that a first load terminal at a first main surface of the vertical power semiconductor die is electrically and physically connected to the die pad and a second load terminal at a second main surface of the vertical power semiconductor die opposite the first main surface faces away from the die pad;
vertically aligning one or more second metallic frames with the first metallic frame, each second metallic frame comprising a plurality of first contact pads and a plurality of second connectors that hold the first contact pads in place;
for each of the first contact pads, attaching the first contact pad to the second load terminal of one of the vertical power semiconductor dies without any direct physical or electrical connection between the first metallic frame and the second metallic frame;
encapsulating the vertical power semiconductor dies in a mold compound such that a surface of the die pads and a surface of the first contact pads that face away from one another are uncovered by the mold compound; and
severing the first connectors and the second connectors to yield individual molded electronic devices.

2. The method of claim 1, wherein each second metallic frame is vertically aligned with the first metallic frame such that the first connectors of the first metallic frame extend in a first lateral direction and the second connectors of each second metallic frame extend in a second lateral direction that is orthogonal to the first lateral direction.

3. The method of claim 1, wherein an individual molded electronic device comprises one or more tabs that protrude from a side face of the mold compound of the individual molded electronic device, each tab comprising a remnant of a severed first connector or a severed second connector.

4. The method of claim 1, wherein severing the first connectors and the second connectors comprises severing the first connectors by cutting along a first lateral direction and severing the second connectors by cutting along a second lateral direction that is orthogonal to the first lateral direction.

5. The method of claim 4,
wherein after severing the first connectors along the first lateral direction, tabs comprising remnants of severed first connectors protrude from the mold compound of individual molded electronic devices along the first lateral direction, and
wherein severing the second connectors comprises cutting the second connectors and a portion of the mold compound using a same cutting tool, such that tabs comprising remnants of severed second connectors are flush with a cut portion of the mold compound of individual molded electronic devices along the second lateral direction.

6. The method of claim 1, wherein attaching a vertical power semiconductor die to a die pad comprises diffusion soldering.

7. The method of claim 1, wherein attaching a first contact pad to a second load terminal of a vertical power semiconductor die comprises at least one of sintering, diffusion soldering, or soldering.

8. The method of claim 1, wherein encapsulating the vertical power semiconductor dies in a mold compound comprises applying the mold compound in discrete segments, wherein each discrete segment of the mold compound encapsulates a subset of the vertical power semiconductors dies.

9. The method of claim 8, wherein the vertical power semiconductor dies of a subset are arranged in one or more rows.

10. The method of claim 8, wherein adjacent discrete segments of the mold compound are separated from one another by one or more first connectors of the first metallic frame.

11. The method of claim 1, wherein encapsulating the vertical power semiconductor dies in a mold compound comprises:
applying the mold compound such that the surface of the first contact pads is covered by the mold compound; and
removing a portion of the mold compound to uncover the surface of the first contact pads.

12. The method of claim 1,
wherein a plurality of second metallic frames are vertically aligned with the first metallic frame,
wherein a subset of the vertical power semiconductor dies comprises all the vertical power semiconductor dies having a second load terminal attached to a first contact pad of a particular second metallic frame, and
wherein the method further comprises testing in parallel each vertical power semiconductor die of the subset, the testing comprising applying a bias to the particular second metallic frame.

13. The method of claim 1,
wherein each vertical power semiconductor die further comprises a control terminal at the second main surface of the vertical power semiconductor die,
wherein each second metallic frame further comprises a plurality of second contact pads and a plurality of third connectors that hold the second contact pads in place, and
wherein the method further comprises:
for each of the second contact pads, attaching the second contact pad to the control terminal of one of the vertical power semiconductor dies without any direct physical or electrical connection between the first metallic frame and the second metallic frame;
encapsulating the vertical power semiconductor dies in the mold compound such that a surface of the second contact pads that faces away from the surface of the die pads is uncovered by the mold compound; and
severing the third connectors to yield individual molded electronic devices.

14. The method of claim 13,
wherein each first load terminal is a drain terminal or collector terminal of a vertical power semiconductor die,
wherein each second load terminal is a source terminal or emitter terminal of a vertical power semiconductor die, and
wherein each control terminal is a gate terminal of a vertical power semiconductor die.

15. A method, comprising:
providing a first metallic frame comprising a plurality of die pads and a plurality of first connectors that hold the die pads in place;
for each of the die pads, attaching a vertical power semiconductor die to the die pad such that a drain or collector terminal at a first main surface of the vertical power semiconductor die is electrically and physically connected to the die pad and a source or emitter terminal and a gate terminal at a second main surface of the vertical power semiconductor die opposite the first main surface face away from the die pad;
vertically aligning one or more second metallic frames with the first metallic frame, each second metallic frame comprising a plurality of first contact pads and a plurality of second connectors that hold the first contact pads in place;
for each of the first contact pads, attaching the first contact pad to the source or emitter terminal of one of the vertical power semiconductor dies without any direct physical or electrical connection between the first metallic frame and the second metallic frame;
encapsulating the vertical power semiconductor dies in a mold compound such that a surface of the die pads and a surface of the first contact pads that face away from one another are uncovered by the mold compound; and
severing the first connectors and the second connectors to yield individual molded electronic devices.

16. The method of claim 15,
wherein each second metallic frame further comprises a plurality of second contact pads and a plurality of third connectors that hold the second contact pads in place, and
wherein the method further comprises:
for each of the second contact pads, attaching the second contact pad to the gate terminal of one of the vertical power semiconductor dies without any direct physical or electrical connection between the first metallic frame and the second metallic frame;
encapsulating the vertical power semiconductor dies in the mold compound such that a surface of the second contact pads that faces away from the surface of the die pads is uncovered by the mold compound; and
severing the third connectors to yield individual molded electronic devices.

17. The method of claim 15, further comprising:
vertically aligning one or more third metallic frames with the first metallic frame, each third metallic frame comprising a plurality of second contact pads and a plurality of third connectors that hold the second contact pads in place;
for each of the second contact pads, attaching the second contact pad to the gate terminal of one of the vertical power semiconductor dies without any direct physical or electrical connection between the first metallic frame and the third metallic frame;
encapsulating the vertical power semiconductor dies in a mold compound such that a surface of the second contact pads that faces away from the surface of the die pads is uncovered by the mold compound; and
severing the third connectors to yield individual molded electronic devices.

18. The method of claim 17,
wherein the die pads of the first metallic frame are provided in rows,
wherein the vertical power semiconductor dies are attached to the die pads such that the gate terminals of the vertical power semiconductor dies arranged on a particular row are oriented away from the gate terminals of the vertical power semiconductor dies arranged on a first adjacent row and the gate terminals of the vertical power semiconductor dies arranged on the particular row are oriented toward the gate terminals of the vertical power semiconductor dies arranged on a second oppositely adjacent row,
wherein a subset of the vertical power semiconductor dies comprises a quantity of the vertical power semiconductor dies on a first row and an equal quantity of the vertical power semiconductor dies on an adjacent second row,
wherein the source or emitter terminals of the vertical power semiconductor dies of the subset on the first row are attached to first contact pads of one particular second metallic frame,
wherein the source or emitter terminals of the vertical power semiconductor dies of the subset on the second row are attached to first contact pads of another particular second metallic frame, and
wherein the gate terminals of all the vertical power semiconductor dies of a subset are attached to second contact pads of a particular third metallic frame.

19. The method of claim 18, wherein the method further comprises testing in parallel each vertical power semiconductor die of a subset, the testing comprising applying a source or emitter bias to each of the particular second metallic frames and applying a gate bias to the particular third metallic frame.

20. A method, comprising:
providing a first metallic frame comprising a plurality of die pads and a plurality of first connectors that hold the die pads in place;
for each of the die pads, attaching two or more vertical power semiconductor dies to the die pad such that a drain or collector terminal at a first main surface of each of the vertical power semiconductor dies is electrically and physically connected to the die pad and a source or emitter terminal and gate terminal at a second main surface of each of the vertical power semiconductor dies opposite the first main surface face away from the die pad;
vertically aligning one or more second metallic frames with the first metallic frame, each second metallic frame comprising a plurality of first contact pads and a plurality of second connectors that hold the first contact pads in place;
for each of the first contact pads, attaching the first contact pad to the source or emitter terminal or gate terminal of one of the vertical power semiconductor dies without any direct physical or electrical connection between the first metallic frame and the second metallic frame;
encapsulating the vertical power semiconductor dies in a mold compound such that a surface of the die pads and a surface of the first contact pads that face away from one another are uncovered by the mold compound; and
severing the first connectors and the second connectors to yield individual molded electronic devices.
